(19) United States
(12) Patent Application Publication
(10) Pub. No.: US 2011/0067845 A1
(43) Pub. Date: Mar. 24, 2011

(54) FAN SHROUD ASSEMBLY

(76) Inventor: Alan Bishop, Naples, FL (US)

(21) Appl. No.: 12/759,251

(22) Filed: Apr. 13, 2010

Related U.S. Application Data
(60) Provisional application No. 61/168,717, filed on Apr. 13, 2009.

(51) Int. Cl. H01L 23/467; F04D 17/00

(52) U.S. Cl. 165/121; 415/182.1

(57) ABSTRACT

A fan shroud assembly for use with a cooling system of a vehicle, the cooling system comprising at least one of a radiator and a fan, the fan shroud assembly comprising: a shroud having a first surface, a second surface, and a sidewall extending therebetween, the first surface connected to at least a portion of the vehicle such that the shroud is at least partially positioned behind the radiator; a shroud nozzle extending from the second surface of the shroud, wherein the shroud nozzle houses at least a portion of the fan; and wherein the fan shroud assembly provides fluid communication between the fan and the radiator, and further wherein the fluid communicated through the fan shroud assembly is substantially evenly distributed over the radiator.

### CROSS-REFERENCE TO RELATED APPLICATION(S)

This application claims the benefit of U.S. Provisional Application Ser. No. 61/168,717 filed Apr. 13, 2009, entitled “FAN SHROUD ASSEMBLY,” which is hereby incorporated herein by reference in its entirety, including all references cited therein.

### BACKGROUND OF THE INVENTION

1. Field of the Invention

The present invention relates in general to fan shrouds and, more particularly, but not by way of limitation, to fan shroud assemblies which improve the efficiency and performance of vehicular engines, as well as fan shroud assemblies which provide for efficacious maintenance of various parts of the vehicle.

2. Background Art

Fan shrouds have been known in art for years. While the fan shroud is a less than frequently seen part of the cooling system, it is extremely important to the overall performance of the engine and thus the vehicle. Crafted from heavy-duty materials, the shroud efficiently cooperates with the radiator fan in maintaining an ideal range of engine operating temperatures. The fan shroud houses the blades of the fan and substantially prevents the blades from damaging other vital engine components. If installed properly, the fan and the fan shroud will effectively communicate heat energy produced by the engine out the engine compartment by facilitating efficient dispersal of heat released from the coolant traveling through the radiator by forcing air over the radiator.

Several drawbacks are common to typical fan shrouds, including, but not limited to, fan shroud design deficiencies resulting in inefficient air flow and shroud and/or engine maintenance issues. Some design deficiencies include fan shrouds that are designed such that the fan is not spaced apart from the radiator at a desired distance, which produces even communication of air over the radiator. For example, some shrouds may position the fan too closely to the radiator, which may lead to uneven air distribution across the outer periphery of the radiator. Also, typical shrouds are fabricated as a solid member or constructed from a single piece of material. Such construction methods produce a fan shroud which, when installed, renders maintenance of the fan and/or other components of the engine extremely difficult and/or problematic. Thus, the entire shroud is typically removed from the engine before the fan and/or other components are worked on.

Therefore the need exists for a fan shroud assembly that allows the fan to be spaced apart from the radiator at a predetermined distance, and a fan shroud assembly that facilitates rapid installation and removal of the same.

### SUMMARY OF THE INVENTION

The present invention is directed to a fan shroud assembly for use with a cooling system of a vehicle, the cooling system comprising at least one of a radiator and a fan, the fan shroud assembly comprising: (a) a shroud having a first surface, a second surface, and a sidewall extending therebetween, the first surface connected to at least a portion of the vehicle such that the shroud is at least partially positioned behind the radiator; (b) a shroud nozzle extending from the second surface of the shroud, wherein the shroud nozzle houses at least a portion of the fan; and (c) wherein the fan shroud assembly provides fluid communication between the fan and the radiator, and further wherein the fluid communicated through the fan shroud assembly is substantially evenly distributed over the radiator. It will be understood that the term “substantially evenly” is defined herein, regardless of its ordinary meaning, to include enhanced distribution of airflow associated with the fan shroud assembly relative to the same without the shroud nozzle as disclosed herein.

In a preferred embodiment of the present invention, the second surface of the shroud and the shroud nozzle each comprise a diameter, wherein the diameter of the shroud nozzle is smaller than the diameter of the second surface of the shroud and wherein the second surface of the shroud and the shroud nozzle are connected via a reduction plate. In this embodiment the reduction plate is preferably angled from the second surface of the shroud to the shroud nozzle.

In another preferred embodiment of the present invention, the shroud nozzle is sized and adapted to receive the entire fan of the vehicle.

In yet another preferred embodiment of the present invention, at least a portion of the shroud nozzle is provided with a protectant covering.

The present invention is also directed to a fan shroud assembly for use with a cooling system of a vehicle, the cooling system comprising at least one of a radiator and a fan, the fan shroud assembly comprising: (a) a shroud having a first surface, a second surface, and a sidewall extending therebetween, the first surface connected to at least a portion of the vehicle such that the shroud is at least partially positioned behind the radiator; (b) a shroud nozzle extending from the second surface of the shroud, wherein the shroud nozzle houses at least a portion of the fan; (c) wherein the fan shroud assembly is divided into a top portion and a bottom portion, wherein the top portion and the bottom portion are releaseably connectable to one another; and (d) wherein the fan shroud assembly provides fluid communication between the fan and the radiator, and further wherein the fluid communicated through the fan shroud assembly is substantially evenly distributed over the radiator.

In a preferred embodiment of the present invention, the top portion and the bottom portion each include an interfacing surface having at least one seal member, wherein when the top portion and the bottom portion are joined together and the interfacing surfaces are disposed in a face-to-face relationship to substantially seal the connection therebetween.

The present invention is also directed to a fan shroud assembly for use with a cooling system of a vehicle, the cooling system comprising at least one of a radiator and a fan, the fan shroud assembly comprising: (a) a shroud having a first surface, a second surface, and a sidewall extending therebetween, the first surface connected to at least a portion of the vehicle such that the shroud is at least partially positioned behind the radiator; (b) a shroud nozzle extending from the second surface of the shroud, wherein the shroud nozzle houses at least a portion of the fan; (c) wherein the second surface of the shroud and the shroud nozzle each comprise a diameter, wherein the diameter of the shroud nozzle is smaller than the diameter of the shroud and wherein the second surface of the shroud and the shroud nozzle are connected via a reduction plate; (d) wherein the fan shroud assembly is divided into a top portion and a bottom portion, wherein the top portion and the bottom portion each include an interfacing surface having at least one seal member, wherein when the top portion and the bottom portion are joined together and the interfacing surfaces are disposed in a face-to-face relationship to substantially seal the connection therebetween; and (e) wherein the fan shroud assembly provides fluid communication between the fan and the radiator, and further wherein the fluid communicated through the fan shroud assembly is substantially evenly distributed over the radiator.

### BRIEF DESCRIPTION OF THE DRAWINGS

Certain embodiments of the present invention are illustrated by the accompanying figures. It will be understood that the figures are not necessarily to scale and that details not necessary for an understanding of the invention or that render other details difficult to perceive may be omitted. It will be understood that the invention is not necessarily limited to the particular embodiments illustrated herein.

The invention will now be described with reference to the drawings wherein:

FIG. 1 of the drawings is an exploded, perspective view of a fan shroud assembly in association with a portion of a cooling system of a vehicle;

FIG. 2 of the drawings is a front elevation view of the fan shroud assembly of FIG. 1;

FIG. 3 of the drawings is a rear elevation view of the fan shroud assembly of FIGS. 1 and 2;

FIG. 4 of the drawings is a perspective view of the fan shroud assembly of FIGS. 1-3; and

FIG. 5 of the drawings is a perspective view of a top portion and a bottom portion of the fan shroud assembly in association with attachment elements.

### DETAILED DESCRIPTION OF THE INVENTION

While this invention is susceptible of embodiment in many different forms, there is shown in the drawings and will herein be described in detail several specific embodiments with the understanding that the present disclosure is to be considered as an exemplification of the principles of the invention and is not intended to limit the invention to the embodiments illustrated.

It will be understood that like or analogous elements and/or components, referred to herein, may be identified throughout the drawings with like reference characters.

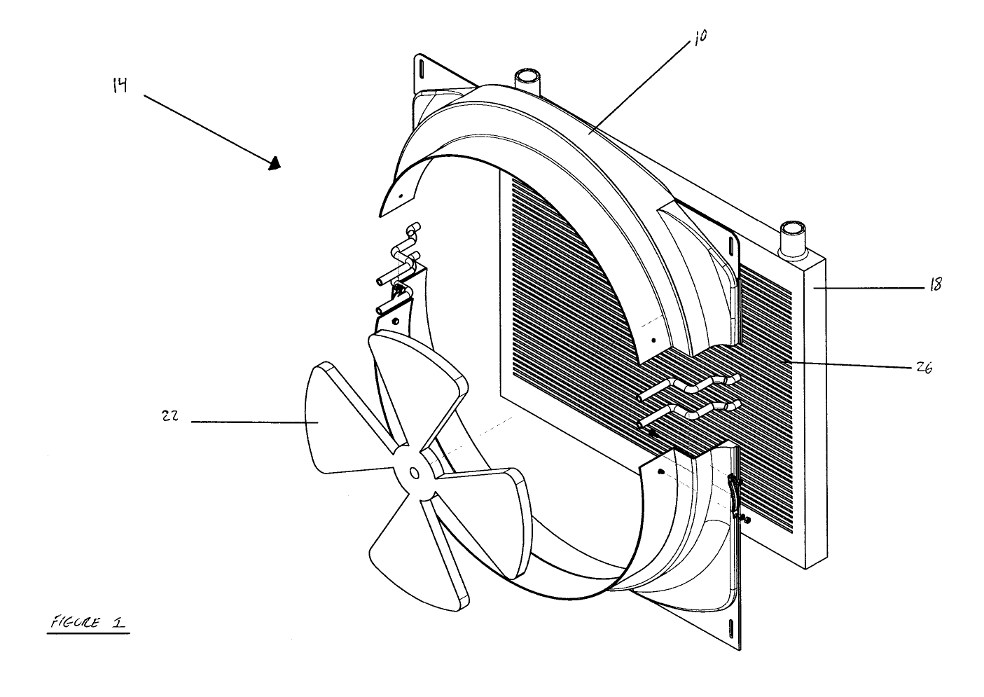

Referring now to the drawings, and to FIG. 1 in particular, shown therein is a fan shroud assembly 10 for use with a portion of a cooling system 14 of a vehicle. More specifically, the cooling system 14 includes at least a radiator 18 and a fan 22. The radiator 18 is disposed proximate the front of the vehicle and is provided with a series of tubes 26 that retain a coolant liquid. The fan 22 communicates air through the fan shroud assembly 10 and over the tubes 26 of the radiator 18 to reduce the temperature of the coolant stored within the tubes 26 of the radiator 18. The fan 22 is disposed at least partially within the fan shroud assembly 10 and in one embodiment, the fan 22 is completely housed within the fan shroud assembly 10.

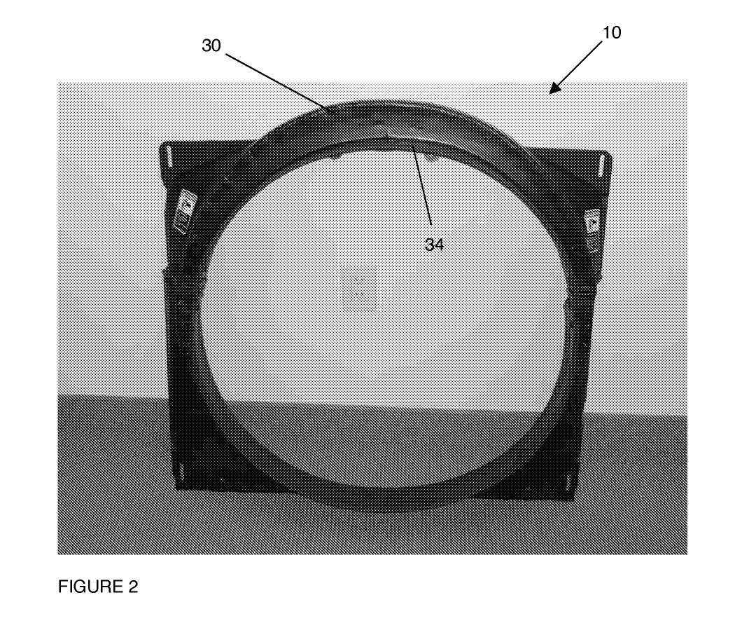

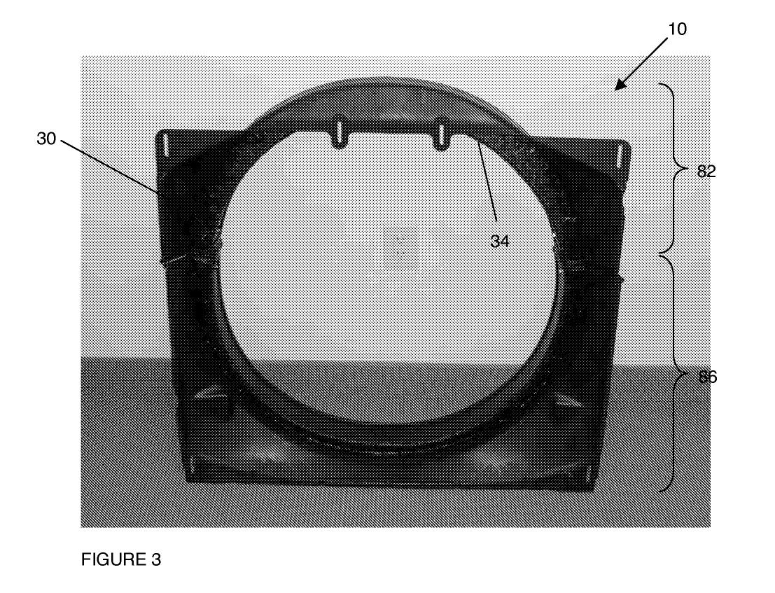

Referring now to FIGS. 1-4 collectively, the fan shroud assembly 10 includes a shroud 30 and a shroud nozzle 34. The fan shroud assembly 10 is provided to enclose the blades of the fan 22 to protect the various components of the engine (not shown) and/or to protect an individual performing maintenance on the same. The shroud 30 may be formed by injection molding of a plastic and/or plastic polymer, although any one of a number of other suitable manufacturing methods and/or materials, for example, a metal or metallic alloy, that would be known to one of ordinary skill in the art having the present disclosure before them are likewise contemplated for use in accordance with the present invention. In one embodiment, the shroud 30 includes a first surface 38, a second surface 42 and a sidewall 46 extending therebetween. The first surface 38 defines a substantially rectangular frame having one or more slots 50 configured to receive one or more fasteners for joining the fan shroud assembly 10 to at least a portion of the vehicle. Examples of fasteners include, but are not limited to, threaded fasteners, nut and bolt fasteners, clips, rivets, adhesives, and the like. The sidewall 46 is formed having a fluid flow passage 52 adapted to direct air flowing from the fan 22 across the radiator 18. The sidewall 46 may be offset from the first surface 38 such that at least a portion of the sidewall 46 is disposed above the first surface 38. The sidewall 46 may preferably include a plurality of flared portions 54 constructed to direct air flowing through the fluid flow passage 52 outwardly towards the outer periphery of the radiator 18 to provide a substantially even distribution of airflow over the radiator 18.

The shroud nozzle 34 is provided with a first surface 58, a second surface 62 and a sidewall 66 extending therebetween forming a substantially tubular fluid flow passage 70 which is preferably disposed in axial alignment with the fluid flow passage 52 of the shroud 30. The shroud nozzle 34 is also preferably sized and adapted to house at least a portion of the fan 22. The shroud nozzle 34 may be fabricated separately from the shroud 30 or formed integrally with shroud 30.

In one embodiment, the shroud nozzle 34 is a substantially tubular cylinder, although it will be understood that shroud nozzles 34 may be constructed having various shapes and cross sectional areas provided the shroud nozzle 34 house the fan 22 and direct air flowing from the fan 22 through and/or to the radiator 18. For example, a shroud nozzle 34 that increases in angle from the second surface 62 to the first surface 58. It will be understood that other shapes and/or configurations that would be known to one of ordinary skill in the art with the present disclosure before them are likewise contemplated for use in accordance with the present invention. Additionally, shroud nozzles 34 with different lengths may be provided to extend the fan 22 at a distance further away from the radiator 18 than with the shroud 30 only.

The second surface 62 of the shroud nozzle 34 is provided with a protectant covering 74 to protect the tips of the blades of the fan 22, for example, a rubber or other durable material that would be known to one of ordinary skill in the art.

The fan shroud assembly 10 may also comprise a reduction plate 78 connected to the second surface 42 of the shroud 30. The reduction plate 78 operates to reduce the diameter of the second surface 42 to change the fluid flow passage 52 of the shroud 30 to more efficiently diffuse the air flowing through the fluid flow passage 52 from the fan 22. In one embodiment, the shroud nozzle 34 is connected to the shroud 30 via the reduction plate 78. It will be understood that the reduction plate 78 may be disposed substantially perpendicular to the radiator 18 and the fan 22. It will be further understood that the reduction plate 78 may also be angled, for example, sloping from the shroud nozzle 34 to the shroud 30.

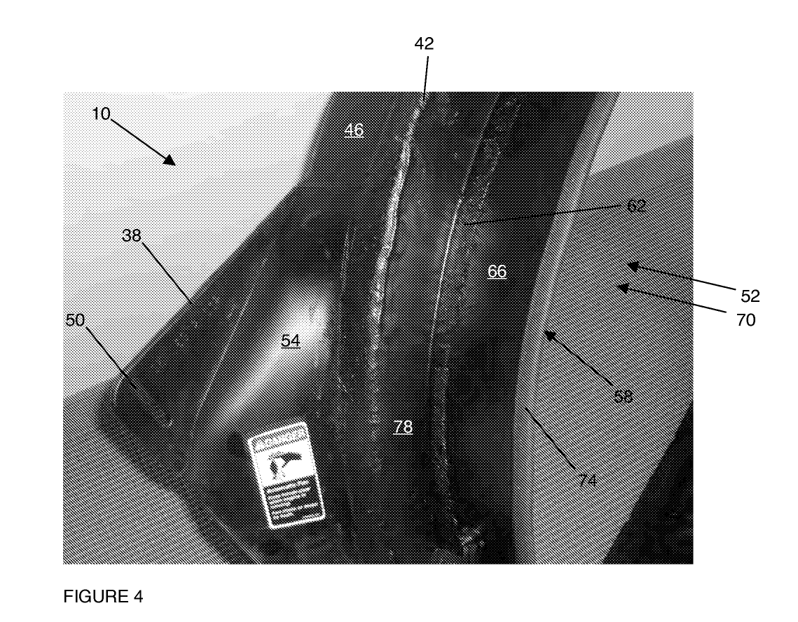

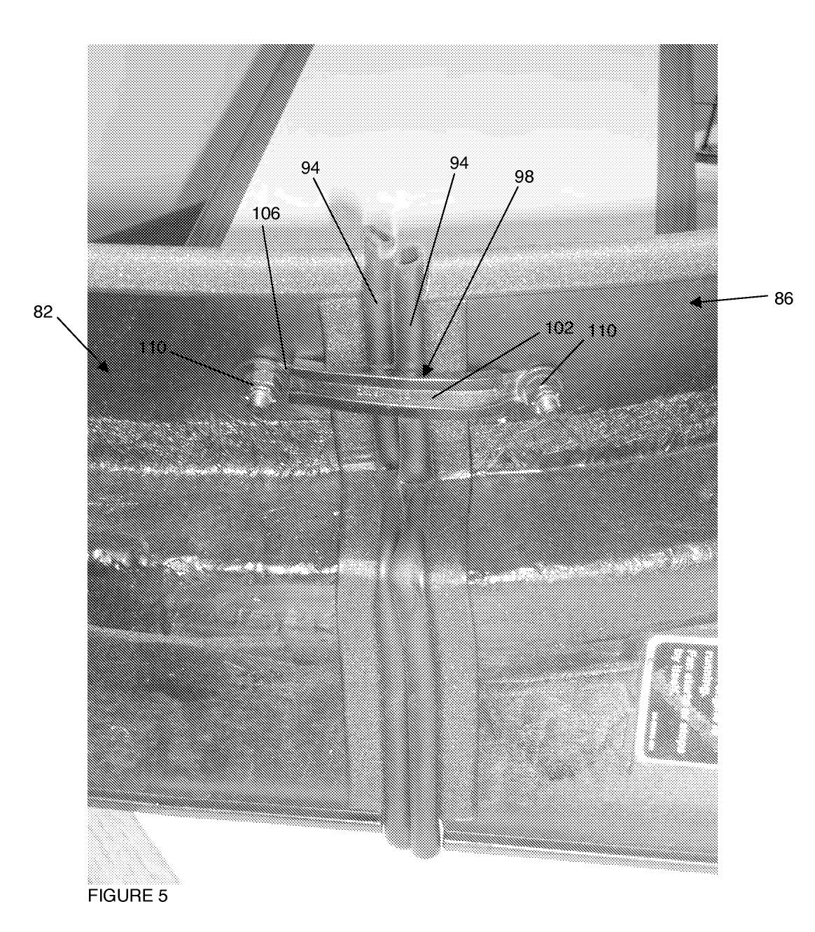

Referring now to FIGS. 4 and 5 collectively, in another embodiment, the fan shroud assembly 10 may be divided into a top portion 82 and a bottom portion 86 for ease of installation and maintenance of various parts of the engine including the fan 22. Both the top portion 82 and the bottom portion 86 each comprise an interface surface 90. The interface surfaces 90 are disposed in a face-to-face relationship when the top portion 82 and the bottom portion 86 are joined together. In one embodiment, the interface surfaces 90 of both the top portion 82 and the bottom portion 86 comprise a seal member 94 disposed along the length of each of the interface surfaces 90. The seal members 94 operate to form a substantially air-tight seal between the top portion 82 and the bottom portion 86 when they are joined together.

The top portion 82 and the bottom portion 86 may be joined together with attachment members 98. In one embodiment, the attachment members 98 include a strap portion 102 having opposing tabs 106 for engaging fasteners 110. The strap portion 102 is preferably constructed of a durable yet resilient material that may be fabricated of a partially elastomeric material, for example, a rubber or plastic polymer. To install the attachment members 98, the top portion 82 and the bottom portion 86 are each provided with apertures (not shown) which permit the insertion of the fasteners 110 therethrough. The top portion 82 and the bottom portion 86 are joined together and the tabs 106 of the attachment members 98 are aligned with the apertures of the top portion 82 and the bottom portion 86. Fasteners 110 are inserted through the apertures and tabs 106 and secured, thereby securing the top portion 82 and the bottom portion 86 together. In another embodiment, although not shown, the attachment members 98 may include clamps that join the top portion 82 and the bottom portion 86 together, although any means for joining the top portion 82 and the bottom portion 86 together that would be known to one of ordinary skill in the art with the present disclosure before them are likewise contemplated for use in accordance with the present invention.

The fan shroud assembly 10 is installed by securing the first surface 38 of the shroud 30 to at least a portion of a vehicle (not shown) such that the shroud 30 is disposed between the radiator 18 and the fan 22. The fan 22 is disposed at least partially within the shroud nozzle 34 of the fan shroud assembly 10. To service the fan 22 or other parts of the vehicle, the top portion 82 of the fan shroud assembly 10 is removed by removing the fasteners 110 that join the attachment members 98 to the top portion 82 and the bottom portion 86 of the fan shroud assembly 10. The removal of the top portion 82 allows for safe and efficient access to the fan 22 and other various parts of the fan shroud assembly 10 without necessitating the complete removal of the fan shroud assembly 10.

The foregoing description merely explains and illustrates the invention and the invention is not limited thereto except insofar as the appended claims are so limited, as those skilled in the art who have the disclosure before them will be able to make modifications without departing from the scope of the invention.

What is claimed is:

1. A fan shroud assembly for use with a cooling system of a vehicle, the cooling system comprising at least one of a radiator and a fan, the fan shroud assembly comprising:
a shroud having a first surface, a second surface, and a sidewall extending therebetween, the first surface connected to at least a portion of the vehicle such that the shroud is at least partially positioned behind the radiator;
a shroud nozzle extending from the second surface of the shroud, wherein the shroud nozzle houses at least a portion of the fan; and
wherein the fan shroud assembly provides fluid communication between the fan and the radiator, and further wherein the fluid communicated through the fan shroud assembly is substantially evenly distributed over the radiator.

2. The fan shroud assembly according to claim 1, wherein the second surface of the shroud and the shroud nozzle each comprise a diameter, wherein the diameter of the shroud nozzle is smaller than the diameter of the second surface of the shroud and wherein the second surface of the shroud and the shroud nozzle are connected via a reduction plate.

3. The fan shroud assembly according to claim 2, wherein the reduction plate is angled from the second surface of the shroud to the shroud nozzle.

4. The fan shroud assembly according to claim 1, wherein the shroud nozzle is sized and adapted to receive the entire fan of the vehicle.

5. The fan shroud assembly according to claim 1, wherein at least a portion of the shroud nozzle is provided with a protectant covering.

6. A fan shroud assembly for use with a cooling system of a vehicle, the cooling system comprising at least one of a radiator and a fan, the fan shroud assembly comprising:
a shroud having a first surface, a second surface, and a sidewall extending therebetween, the first surface connected to at least a portion of the vehicle such that the shroud is at least partially positioned behind the radiator;
a shroud nozzle extending from the second surface of the shroud, wherein the shroud nozzle houses at least a portion of the fan;
wherein the fan shroud assembly is divided into a top portion and a bottom portion, wherein the top portion and the bottom portion are releaseably connectable to one another; and
wherein the fan shroud assembly provides fluid communication between the fan and the radiator, and further wherein the fluid communicated through the fan shroud assembly is substantially evenly distributed over the radiator.

7. The fan shroud assembly according to claim 6, wherein the second surface of the shroud and the shroud nozzle each comprise a diameter, wherein the diameter of the shroud nozzle is smaller than the diameter of the second surface of the shroud and wherein the second surface of the shroud and the shroud nozzle are connected via a reduction plate.

8. The fan shroud assembly according to claim 7, wherein the reduction plate is angled from the second surface of the shroud to the shroud nozzle.

9. The fan shroud assembly according to claim 6, wherein the shroud nozzle is sized and adapted to receive the entire fan of the vehicle.

10. The fan shroud assembly according to claim 6, wherein at least a portion of the shroud nozzle is provided with a protectant covering.

11. The fan shroud assembly according to claim 6, wherein the top portion and the bottom portion each include an interfacing surface having at least one seal member, wherein when the top portion and the bottom portion are joined together and the interfacing surfaces are disposed in a face-to-face relationship to substantially seal the connection therebetween.

12. A fan shroud assembly for use with a cooling system of a vehicle, the cooling system comprising at least one of a radiator and a fan, the fan shroud assembly comprising:
a shroud having a first surface, a second surface, and a sidewall extending therebetween, the first surface connected to at least a portion of the vehicle such that the shroud is at least partially positioned behind the radiator;
a shroud nozzle extending from the second surface of the shroud, wherein the shroud nozzle houses at least a portion of the fan;
wherein the second surface of the shroud and the shroud nozzle each comprise a diameter, wherein the diameter of the shroud nozzle is smaller than the diameter of the shroud and wherein the second surface of the shroud and the shroud nozzle are connected via a reduction plate;
wherein the fan shroud assembly is divided into a top portion and a bottom portion, wherein the top portion and the bottom portion each include an interfacing surface having at least one seal member, wherein when the top portion and the bottom portion are joined together and the interfacing surfaces are disposed in a face-to-face relationship to substantially seal the connection therebetween; and
wherein the fan shroud assembly provides fluid communication between the fan and the radiator, and further wherein the fluid communicated through the fan shroud assembly is substantially evenly distributed over the radiator.

13. The fan shroud assembly according to claim 12, wherein the reduction plate is angled from the second surface of the shroud to the shroud nozzle.

14. The fan shroud assembly according to claim 12, wherein the shroud nozzle is sized and adapted to receive the entire fan of the vehicle.

15. The fan shroud assembly according to claim 12, wherein at least a portion of the shroud nozzle is provided with a protectant covering.
